(19) United States
(12) Patent Application Publication
(10) Pub. No.: US 2024/0250078 A1
(43) Pub. Date: Jul. 25, 2024

(54) ELECTRONIC DEVICE AND METHOD FOR MANUFACTURING THE SAME

(71) Applicant: InnoLux Corporation, Miao-Li County (TW)

(72) Inventors: Wan-Yu LEE, Miao-Li County (TW); Shan-Shan HSU, Miao-Li County (TW); Chia-Chieh FAN, Miao-Li County (TW)

(21) Appl. No.: 18/404,584

(22) Filed: Jan. 4, 2024

Related U.S. Application Data
(60) Provisional application No. 63/439,997, filed on Jan. 19, 2023.

(30) Foreign Application Priority Data
Sep. 21, 2023 (CN) 202311223419.9

(51) Int. Cl. H01L 25/16; H01L 33/56

(52) U.S. Cl. CPC H01L 25/167; H01L 33/56; H01L 2933/005

(57) ABSTRACT

An electronic device and a method for manufacturing the same are provided. The method for manufacturing the electronic device comprises the following steps: forming a protective layer on a plurality of electronic units; disposing the plurality of electronic units with the protective layer and a plurality of driving units on a substrate, respectively; forming a color layer on the plurality of electronic units with the protective layer, the plurality of driving units and the substrate; and removing the color layer on the plurality of electronic units with the protective layer.

### CROSS-REFERENCE TO RELATED APPLICATIONS

This application claims the benefits of the Chinese Patent Application Serial Number 202311223419.9, filed on Sep. 21, 2023, the subject matter of which is incorporated herein by reference.

This application claims the benefit of filing date of U.S. Provisional Application Ser. No. 63/439,997, filed Jan. 19, 2023 under 35 USC § 119(e)(1).

### BACKGROUND

### Field

The present disclosure relates to an electronic device and a method for manufacturing the same. More specifically, the present disclosure relates to an electronic device comprising a color layer and a method for manufacturing the same.

### Description of Related Art

As technology advances, display technology continues to improve. At the same time, in order to meet consumers' requirements for display quality of display devices, manufacturers are all committed to improving the display quality of display devices.

The light-emitting module in the display device will affect the display quality. A reflective layer is provided in the conventional light-emitting module to increase the amount of light emitted by the light-emitting module, thereby improving the display effect of the display device. However, in order to improve the utilization efficiency of the reflective layer, multiple procedures for preparing the reflective layer are required, which results in disadvantages such as complicated process steps, time-consuming process, or high cost.

Therefore, it is desirable to provide a method for manufacturing an electronic device to improve the aforesaid shortcomings.

### SUMMARY

The present disclosure provides a method for manufacturing an electronic device, which comprises the following steps: forming a protective layer on a plurality of electronic units; disposing the plurality of electronic units with the protective layer and a plurality of driving units on a substrate respectively; forming a color layer on the plurality of electronic units with the protective layer, the plurality of driving units and the substrate; and removing the color layer on the plurality of electronic units with the protective layer.

The present disclosure further provides an electronic device, which comprises: a substrate; a plurality of electronic units disposed on the substrate; a plurality of driving units disposed on the substrate; a protective layer disposed on the plurality of electronic units; and a color layer disposed on the substrate and the plurality of driving units.

Other novel features of the disclosure will become more apparent from the following detailed description when taken in conjunction with the accompanying drawings.

### BRIEF DESCRIPTION OF DRAWINGS

FIG. 1A to FIG. 1D are schematic views showing a method for manufacturing an electronic device according to one embodiment of the present disclosure.

FIG. 2 is a schematic view of an electronic device according to one embodiment of the present disclosure.

### DETAILED DESCRIPTION

The following is specific embodiments to illustrate the implementation of the present disclosure. Those who are familiar with this technique can easily understand the other advantages and effects of the present disclosure from the content disclosed in the present specification. The present disclosure can also be implemented or applied by other different specific embodiments, and various details in the present specification can also be modified and changed according to different viewpoints and applications without departing from the spirit of the present disclosure.

It should be noted that, in the present specification, when a component is described to have an element, it means that the component may have one or more of the elements, and it does not mean that the component has only one of the element, except otherwise specified. Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

In the specification and the appended claims of the present disclosure, certain words are used to refer to specific elements. Those skilled in the art should understand that electronic device manufacturers may refer to the same components by different names. The present specification does not intend to distinguish between elements that have the same function but have different names. In the following description and claims, words such as “comprising”, “including”, “containing”, and “having” are open-ended words, so they should be interpreted as meaning “containing but not limited to . . . ”. Therefore, when the terms “comprising”, “including”, “containing” and/or “having” are used in the description of the present disclosure, they specify the existence of corresponding features, regions, steps, operations and/or components, but do not exclude the existence of one or more corresponding features, regions, steps, operations and/or components.

The terms, such as “about”, “equal to”, “equal” or “same”, “substantially”, or “approximately”, are generally interpreted as within 10%, 5%, 3%, 2%, 1%, or 0.5% of a given value or range. The quantity given here is an approximate quantity, that is, without specifying “about”, “approximately”, “substantially” and “approximately”, “about”, “approximately”, “substantially” and “approximately” can still be implied. Furthermore, when a value is “in a range from a first value to a second value” or “in a range between a first value and a second value”, the value can be the first value, the second value, or another value between the first value and the second value.

In the present specification, except otherwise specified, the terms (including technical and scientific terms) used herein have the meanings generally known by a person skilled in the art. It should be noted that, except otherwise specified, in the embodiments of the present disclosure, these terms (for example, the terms defined in the generally used dictionary) should have the meanings identical to those known in the art, the background of the present disclosure or the context of the present specification, and should not be read by an ideal or over-formal way.

In addition, relative terms such as “below” or “under” and “on”, “above” or “over” may be used in the embodiments to describe the relative relationship between one element and another element in the drawings. It will be understood that if the device in the drawing was turned upside down, elements described on the “lower” side would then become elements described on the “upper” side. When a unit (for example, a layer or a region) is referred to as being “on” another unit, it can be directly on the another unit or there may be other units therebetween. Furthermore, when a unit is said to be “directly on another unit”, there is no unit therebetween. Moreover, when a unit is said to be “on another unit”, the two have a top-down relationship in a top view, and the unit can be disposed above or below the another unit, and the top-bottom relationship depends on the orientation of the device.

Furthermore, any two values or directions used for comparison may have certain errors. If the first value is equal to the second value, it implies that there may be an error of about 10% between the first value and the second value. If the first direction is perpendicular to the second direction, the angle between the first direction and the second direction may be between 80° and 100°. If the first direction is parallel to the second direction, the angle between the first direction and the second direction may be between 0° and 10°.

It should be noted that the technical solutions provided by different embodiments hereinafter may be replaced, combined or used in combination, so as to constitute another embodiment without violating the spirit of the present disclosure.

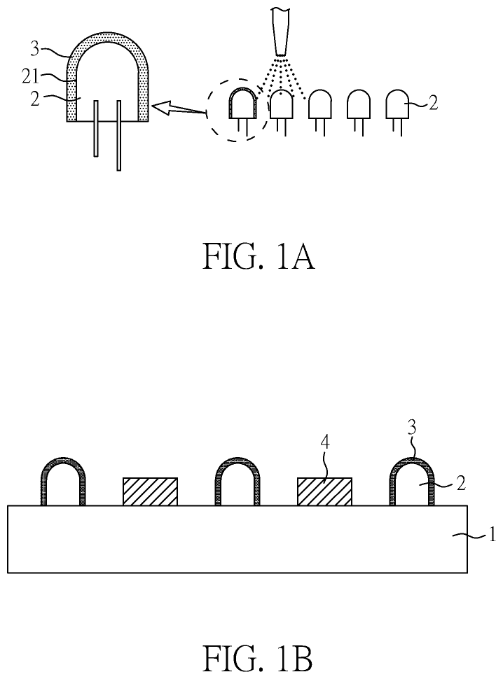

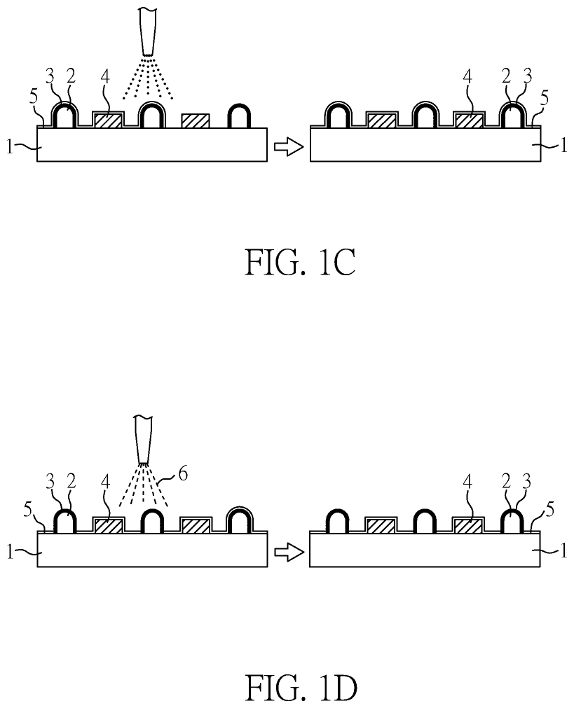

FIG. 1A to FIG. 1D are schematic views showing a method for manufacturing an electronic device according to one embodiment of the present disclosure.

In one embodiment of the present disclosure, the method for manufacturing the electronic device may comprise the following steps: forming a protective layer 3 on a plurality of electronic units 2. More specifically, as shown in FIG. 1A, the protective layer 3 may be formed on the surfaces 21 of the electronic units 2 by, for example, spray coating. Herein, the spraying coating is used as an example in FIG. 1A. In other embodiments of the present disclosure, the protective layer 3 may be formed by other suitable methods, such as dip coating, deposition or a combination thereof, but the present disclosure is not limited thereto.

In one embodiment of the present disclosure, the electronic units 2 may be, for example, light emitting diodes and varactor diodes, wherein the light emitting diodes may comprise, for example, organic light emitting diodes (OLEDs), mini light emitting diodes (mini LEDs), micro LEDs or quantum dot LEDs (which may comprise QLEDs, QDLEDs), fluorescence, phosphor or other suitable materials, or a combination thereof, but the present disclosure is not limited thereto. In one embodiment of the present disclosure, the electronic units 2 may be passive units, such as capacitors, resistors, other passive components or a combination thereof, but the present disclosure is not limited thereto. In one embodiment of the present disclosure, the protective layer 3 may comprise a release layer, a peelable adhesive layer or a combination thereof, but the present disclosure is not limited thereto. In one embodiment of the present disclosure, the protective layer 3 may comprise silicon mold release agent, fluorine mold release agent, polyethylene mold release agent, polypropylene mold release agent, paraffin mold release agent, montan wax mold release agent, carnauba mold release agent or a combination thereof, but the present disclosure is not limited thereto. In one embodiment of the present disclosure, the material of the protective layer 3 may comprise silicone oil, mineral oil, wax, a fatty acid derivative, ethylene glycol, polyvinyl alcohol (PVA), polytetrafluoroethylene (PTFE), fluorinated ethylene propylene (FEP), stearic acid or a combination thereof, but the present disclosure is not limited thereto.

Next, as shown in FIG. 1B, the electronic units 2 with the protective layer 3 and a plurality of driving units 4 are respectively disposed on the substrate 1. In the present disclosure, the electronic units 2 and the driving units 4 may be respectively disposed on the substrate 1 through the bonding method such as welding, flip-chip bonding, Cu—Cu hybrid bonding or a combination thereof, but the present disclosure is not limited to the aforesaid bonding methods. In addition, the method for disposing the electronic units 2 and the driving units 4 may be the same or different.

In the present disclosure, the driving units 4 may be, for example, integrated circuits (ICs), but the present disclosure is not limited thereto. In the present disclosure, the substrate 1 may be a rigid substrate or a flexible substrate. The material of the substrate 1 may include quartz, glass, wafer, sapphire, ceramic materials, resin, epoxy resin, polycarbonate (PC), polyimide (PI), polypropylene (PP), polyethylene terephthalate (PET), polymethylmethacrylate (PMMA), other plastic materials or a combination thereof, but the present disclosure is not limited thereto. In the present disclosure, the shape of the substrate 1 is not particularly limited. For example, the shape of the substrate 1 may be plane, curved or irregular, but the present disclosure is not limited thereto.

Then, a color layer 5 is formed on the electronic units 2 with the protective layer 3, the driving units 4 and the substrate 1. More specifically, as shown in FIG. 1C, the color layer 5 may be formed on the electronic units 2, the driving units 4 and the substrate 1 by, for example, spray coating. Herein, the spraying coating is used as an example in FIG. 1C. In other embodiments of the present disclosure, other suitable methods may be used to form the color layer 5, such as dip coating, spin coating, roller coating, blade coating, deposition or a combination thereof, but the present disclosure is not limited thereto.

In the present disclosure, the color layer 5 may be, for example, a white color layer, a grey color layer or a black color layer, but the present disclosure is not limited thereto. In one embodiment of the present disclosure, the material of the color layer 5 may include, for example, metal, ink or a combination thereof. The metal may include gold, silver, copper, aluminum, or a combination thereof, but the present disclosure is not limited thereto. The material of the ink may include, for example, polyimide (PI), epoxy resin, acrylic resin, polyurethane resin (PU), polyketone resin, phenolic resin, ethylene vinyl acetate (EVA), melamine resin, polysiloxane, polyisoprene, polyester resin or a combination thereof, but the present disclosure is not limited thereto. In one embodiment of the present disclosure, the color layer 5 and the protective layer 3 have different affinities. In one embodiment of the present disclosure, when the color layer 5 is a white color layer and the electronic units 2 are light-emitting diodes, the color layer 5 may be used to reflect the light provided by the light-emitting diodes, thereby improving the light emitting efficiency of the electronic device.

Next, the color layer 5 on the electronic units 2 with the protective layer 3 is removed. More specifically, as shown in FIG. 1D, for example, the electronic units 2 with the protective layer 3, the driving units 4 and the substrate 1 may be washed with a solvent 6 to remove the color layer 5 on the electronic units 2 with the protective layer 3, but the present disclosure is not limited thereto. In other embodiments of the present disclosure, other suitable methods may be used to remove the color layer 5 on the electronic units 2 with the protective layer 3. For example, the color layer 5 on the electronic units 2 with the protective layer 3 may be peeled off with an external force, but the present disclosure is not limited thereto.

In the present disclosure, the solvent 6 may comprise water, a surfactant, ethanol, acetone, isopropyl alcohol or a combination thereof, but the present disclosure is not limited thereto. In one embodiment of the present disclosure, the surfactant may be, for example, dimethyl silicone oil cleaning agent, but the present disclosure is not limited thereto.

In the present disclosure, the protective layer 3 is formed on the electronic units 2 in advance, so the subsequent steps of forming the color layer 5 may be simplified (for example, the number of processes for forming the color layer 5 may be simplified), thus achieving the advantage of saving process time or cost. In addition, since the color layer 5 and the protective layer 3 have different affinities, it is easy to perform subsequent steps of removing the color layer 5 on the electronic unit 2 with the protective layer 3, thus achieving the advantage of simplifying the manufacturing process.

In one embodiment of the present disclosure, the method may further comprise a step of: curing the color layer 5 at a predetermined temperature after the step of forming the color layer 5 on the electronic units 2 with the protective layer 3, the driving units 4 and the substrate 1. In this way, the adhesion of the color layer 5 may be improved (for example, the effect of the color layer 5 adhering to the substrate 1 and/or the driving units 4 may be improved). Therefore, in the subsequent step of removing the color layer 5, the peeling risk of the color layer 5 that is not expected to be removed may be reduced and the reliability of color layer 5 may be improved. In the present disclosure, the predetermined temperature may range from 50° C. to 200° C., for example, from 50° C. to 180° C., 50° C. to 150° C., 50° C. to 130° C., 70° C. to 200° C., 70° C. to 180° C., 70° C. to 150° C. or 70° C. to 130° C., but the present disclosure is not limited thereto.

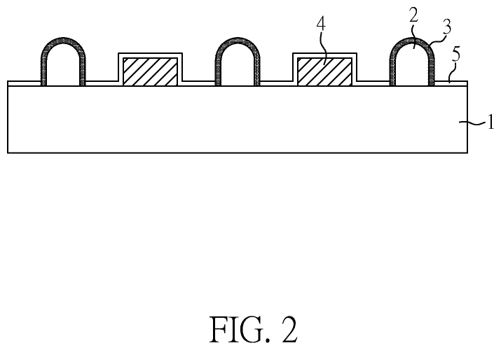

FIG. 2 is a schematic view of an electronic device according to one embodiment of the present disclosure.

In one embodiment of the present disclosure, the electronic device manufactured by the aforesaid process may be shown, for example, in FIG. 2. The electronic device may comprise: a substrate 1; a plurality of electronic units 2 disposed on the substrate 1; a plurality of driving units 4 disposed on the substrate 1; a protective layer 3 disposed on the electronic units 2; and a color layer 5 disposed on the substrate 1 and the driving units 4. In the present disclosure, the substrate 1, the electronic units 2, the driving units 4, the protective layer 3 and the color layer 5 may be as described above and are not described again.

In one embodiment of the present disclosure, as shown in FIG. 2, part of the color layer 5 may be in contact with the protective layer 3. In other words, there is no gap between part of the color layer 5 and the protective layer 3. Therefore, when the color layer 5 is a white color layer and the electronic units 2 are light-emitting diodes, the amount of light emitted by the light-emitting diodes may be increased, thereby improving the light utilization efficiency. In one embodiment of the present disclosure, as shown in FIG. 2, the electronic units 2 and the driving units 4 are disposed on the same side of the substrate 1.

In one embodiment of the present disclosure, as shown in FIG. 2, the protective layer 3 is not disposed on the driving units 4, thereby improving the reliability of the color layer 5 disposed on driving units 4. In one embodiment of the present disclosure, as shown in FIG. 2, the color layer 5 is not disposed on the electronic units 2; thus, the light emitting efficiency of the light-emitting diodes may be improved when the electronic units 2 are the light-emitting diodes.

In the present disclosure, surface chemical analysis may be performed by atomic absorption spectroscopy (AAS), Fourier-transform infrared spectroscopy (FTIR), scanning electron microscope-energy dispersive spectrometer (SEM-EDS), other suitable analytical methods or a combination thereof, to confirm the setting of the protective layer 3 on the electronic units 2.

In the present disclosure, the electronic device may include a light emitting module, a display device, a backlight device, an antenna device, a sensing device, a tiled device, a touch electronic device (touch display), a curved electronic device (curved display) or a non-rectangular electronic device (free shape display), but the present disclosure is not limited thereto. The display device may include, for example, liquid crystals, light emitting diodes, fluorescence, phosphors, other suitable display media or a combination thereof, but the present disclosure is not limited thereto. The display device may be a non-self-luminous display device or a self-luminous display device; the antenna device may be a liquid crystal antenna device or a varactor antenna device; the sensing device may be a sensing device that senses capacitance, light, heat or ultrasonic waves; but the present disclosure is not limited thereto. The tiled device may be, for example, a tiled display device or a tiled antenna device, but the present disclosure is not limited thereto. The electronic device may be any combination of the above, but the present disclosure is not limited thereto. In addition, the electronic device may be a bendable or flexible electronic device. The shape of the electronic device may be a rectangle, a circle, a polygon, a shape with curved edges, or other suitable shapes. Furthermore, the electronic device may have peripheral systems such as drive systems, control systems, light source systems, shelf systems, etc. to support display devices, antenna devices, wearable devices (for example, including augmented reality (AR) or virtual reality (VR) devices), vehicle devices (for example, including car windshield) or tiled devices.

Although the present disclosure has been explained in relation to its embodiment, it is to be understood that many other possible modifications and variations can be made without departing from the spirit and scope of the disclosure as hereinafter claimed.

1. A method for manufacturing an electronic device, comprising the following steps:
forming a protective layer on a plurality of electronic units;
disposing the plurality of electronic units with the protective layer and a plurality of driving units on a substrate, respectively;
forming a color layer on the plurality of electronic units with the protective layer, the plurality of driving units and the substrate; and
removing the color layer on the plurality of electronic units with the protective layer.

2. The method of claim 1, wherein the protective layer comprises a release layer, a peelable adhesive layer or a combination thereof.

3. The method of claim 1, wherein the protective layer comprises silicon mold release agent, fluorine mold release agent, polyethylene mold release agent, polypropylene mold release agent, paraffin mold release agent, montan wax mold release agent, carnauba mold release agent or a combination thereof.

4. The method of claim 1, wherein a material of the protective layer comprises silicone oil, mineral oil, wax, a fatty acid derivative, ethylene glycol, polyvinyl alcohol, polytetrafluoroethylene, fluorinated ethylene propylene, stearic acid or a combination thereof.

5. The method of claim 1, further comprising a step of: curing the color layer at a predetermined temperature after the step of forming the color layer on the plurality of electronic units with the protective layer, the plurality of driving units and the substrate.

6. The method of claim 5, wherein the predetermined temperature ranges from 50° C. to 200° C.

7. The method of claim 1, wherein the step of removing the color layer on the plurality of electronic units with the protective layer comprises: washing the plurality of electronic units with the protective layer, the plurality of driving units and the substrate with a solvent.

8. The method of claim 7, wherein the solvent comprises water, a surfactant, ethanol, acetone, isopropyl alcohol or a combination thereof.

9. The method of claim 1, wherein the step of removing the color layer on the plurality of electronic units with the protective layer comprises: peeling off the color layer on the plurality of electronic units with the protective layer with an external force.

10. The method of claim 1, wherein the color layer is a white color layer, a grey color layer or a black color layer.

11. The method of claim 1, wherein the plurality of electronic units are light emitting diodes.

12. An electronic device, comprising:
a substrate;
a plurality of electronic units disposed on the substrate;
a plurality of driving units disposed on the substrate;
a protective layer disposed on the plurality of electronic units; and
a color layer disposed on the substrate and the plurality of driving units.

13. The electronic device of claim 12, wherein part of the color layer is in contact with the protective layer.

14. The electronic device of claim 12, wherein the protective layer is not disposed on the plurality of driving units, and the color layer is not disposed on the plurality of electronic units.

15. The electronic device of claim 12, wherein the plurality of electronic units and the plurality of driving units are disposed on the same side of the substrate.

16. The electronic device of claim 12, wherein the protective layer comprises a release layer, a peelable adhesive layer or a combination thereof.

17. The electronic device of claim 12, wherein the protective layer comprises silicon mold release agent, fluorine mold release agent, polyethylene mold release agent, polypropylene mold release agent, paraffin mold release agent, montan wax mold release agent, carnauba mold release agent or a combination thereof.

18. The electronic device of claim 12, wherein a material of the protective layer comprises silicone oil, mineral oil, wax, a fatty acid derivative, ethylene glycol, polyvinyl alcohol, polytetrafluoroethylene, fluorinated ethylene propylene, stearic acid or a combination thereof.

19. The electronic device of claim 12, wherein the color layer is a white color layer, a grey color layer or a black color layer.

20. The electronic device of claim 12, wherein the plurality of electronic units are light emitting diodes.
